(19) United States
(12) Patent Application Publication
(10) Pub. No.: US 2005/0161322 A1
(43) Pub. Date: Jul. 28, 2005

(54) Replaceable target sidewall insert with texturing

(75) Inventor: David B. Smathers, Columbus, OH (US)

Correspondence Address: Wegman Hessler & Vanderburg, Suite 200, 6055 Rockside Woods Boulevard, Cleveland, OH, 44131, US

(73) Assignee: Tosoh SMD, Inc

(21) Appl. No.: 10/512,304

(22) PCT Filed: Mar. 26, 2003
(86) PCT No.: PCT/US03/09369

(30) Foreign Application Priority Data
May 20, 2002 (US) 60381914

(51) Int. Cl. C23C 14/35

(52) U.S. Cl. 204/298.12; 204/298.13

(57) ABSTRACT

This invention provides a sputter target (30) and backing plate (60) assembly having a replaceable sputter target sidewall insert (10). The replaceable sidewall insert (10) enhances the effectiveness and useful life of the assembly by replacing only the insert portion of the sidewall (10) when needed, while retaining the remaining portions of the target (30) for additional use. The sidewall insert (10) is secured to the target (30) and backing plate (60) in corresponding grooves (66) provided in the target (30) and backing plate (60). A textured surface (16) such as a continuous textured coating may be applied to the sidewall insert (10) to further enhance particle retention properties of the target/backing plate assembly.

### BACKGROUND OF THE INVENTION

1. Field of Invention

This invention relates to target sidewalls, and in particular to a replaceable target sidewall with textured surface. Replacement of the target sidewall extends the life of the target and increases the retention of deposited material on the target sidewalls.

2. Description of Related Art

In typical sputtering processes, metal atoms, from a metal or metal alloy sputter target are deposited onto a substrate in a physical vapor deposition (PVD) atmosphere. Most of the sputtered metal atoms travel, as desired, directly to the substrate. However, a significant portion of the sputtered particles become scattered in the gas during the PVD process and can deposit on various unintended surfaces of the chamber, such as the shield, or the target itself.

The scattered sputtered particles that deposit onto the various undesired surfaces of the sputter chamber such as the target sidewall, shield or other chamber component, tend to build-up and flake off during later sputtering processes. Deposition of scattered sputtered particles on the target is especially troublesome. For instance, the repeated heating and cooling of the target, including the undesired deposited particles on the sidewalls of the target, render flaking of the particles even more likely.

In many cases, these particles are propelled to the substrate and cause deleterious results in the uniformity of the sputtered coating. Accumulation of particles onto the shield may be remedied by replacement of the shield. Heretofore, the target sidewall itself could not be readily replaced.

Conventional targets were often provided with smooth sidewalls from which the deposited particles would flake off easily and contaminate the chamber and the coating uniformity. In order to improve retention of these deposited particles, the sidewalls were often roughened by bead blasting. Later improvements included arc spraying to increase the roughness of the sidewalls even more. A portion of the target could also be made to overhang the textured surfaces of the sidewalls to further inhibit deposition of scattered particles on the sidewalls. All of these prior art alterations were intended to improve the performance of the target, while inhibiting accumulation and improving retention of undesirable deposit particles on the target, thereby increasing the useful life of a target.

Target life time should be determined primarily by target thickness. However, in the case of N₂ reactive sputtering of Ti targets, the target life is often limited by accumulation of TiN deposits on the target, particularly on the sidewall portion.

The prior art approach of bead blasting has not proven totally successful in eliminating flaking off of undesired particles, particularly TiN particles. For example, the amount of deposited material cannot be held firmly by bead blasting and the embedded blasting media itself may not hold the TiN at all and can actually serve as a particle generator. Arc spraying appears to be the best alternative, but the undesirable TiN deposits must still be made to adhere to the target throughout its useful life.

Accordingly, there is a need in the art for an effective way in which a replaceable target sidewall may be provided so that it may be replaced along with other normally replaceable system components such as shields and the like. Additionally, it is desirable to provide a replaceable target sidewall that is treated, as by texturing, to increase retention of deposited particles thereon.

### SUMMARY OF THE INVENTION

This invention provides a sputter target and backing plate assembly having a replaceable sputter target sidewall insert. The replaceable sidewall insert enhances the effectiveness and useful life of the assembly by replacing only the insert portion of the sidewall when needed, while retaining the remaining portions of the target for additional use.

This invention separately provides that the replaceable sidewall insert is fitted into a groove provided around the circumference of the target and a corresponding groove in the backing plate. The sidewall insert could thus be formed as a cross-sectionally L-shaped ring member fitting into the respective, communicating grooves of the target and backing plate around the target/backing plate assembly.

This invention separately provides a sidewall insert removably fitted to the target and backing plate, wherein the sidewall insert is comprised of a textured surface. The textured surface enhances the retention of particles deposited thereon. The textured surface may be an arc sprayed surface comprised of, for example, Al or Cu or alloys thereof and the like. In all of the exemplary embodiments, the textured coating on the sidewall is selected to roughen or texture the surface to result in less stress to the particles deposited thereon. The textured surface could be provided by bead blasting, knurling, etching, machining or other conventional means. Additionally, foamed metals can be used as the replaceable sidewall insert. These materials themselves have textured surface by their very nature. Foamed Al, Ni, and Cu metals are commercially available.

The sidewall insert could also be composed of a shaped memory metal such as the various nickel-titanium alloys known in the art. These metals can be “trained” to take on a predetermined shape in response to a stimulus such as a change in temperature. For example, the trained state could be an expanded state or shape in which the insert could be readily removed from the target/backing plate assembly.

Also, the insert could be composed of a metal having a negative coefficient of thermal expansion. For example, Zr and some Zr alloys exhibit this property upon cooling of the target/backing plate assembly, the Zr insert could be readily removed from the assembly in its relaxed, expanded state.

In various exemplary embodiments of the invention, the removable sidewall insert is a deep drawn L-shaped ring having a continuous coating, wherein the ring is press fitted and friction fit in the assembly using spring tension from the ring against a lip, forming part of a groove on the target, and an outer wall, forming part of a groove on the backing plate.

In still other exemplary embodiments of the invention, the removable sidewall insert comprises a ring having a pre-thinned area that aids installation into the corresponding grooves of the target and backing plate. The pre-thinned area may simply be cut in order to facilitate removal of the sidewall insert. A new removable sidewall insert may then be installed in place of the removed sidewall insert.

In all of the various exemplary embodiments of the invention, the removable sidewall insert is removably secured to the target and/or backing plate so that the sidewall insert can be removed and replaced with another sidewall insert when the effectiveness of the preceding sidewall insert is exhausted due to meeting or exceeding a threshold value of depositioned particles thereon. For example, double-sided electrically conductive adhesive tape may be used to secure the insert to the assembly, or screws may be used to secure the insert to the assembly. Other fastening devices such as bayonet mounts or ball detent mounts may be used to secure the insert to the assembly provided the removable sidewall insert is easily attachable and removable from the assembly when desired.

In all of the exemplary embodiments the sidewall insert can be replaced as often as desired. For example, if desired, the sidewall insert can be changed every time the shield of the sputter chamber is changed. In this manner, the life of the target is increased as the shield of the sputter chamber and the target sidewall insert can be replaced whenever each, or both, reach a minimum threshold value.

A tool specifically designed for inserting and removal of the sidewall insert may be used to snap fit the insert in place in the various exemplary embodiments described, and/or to cut or otherwise remove the insert from the grooves of the target and backing plate of the invention. The sidewall could be provided with serrated portions extending axially at one or more circumferentially spaced locations. A tool could be inserted behind these to easily cut the sidewall to facilitate easy removal from the target/backing plate assembly.

These and other features and advantages of this invention are described in, or are apparent from, the following detailed description of various exemplary embodiments of the systems and methods according to this invention.

### BRIEF DESCRIPTION OF THE DRAWINGS

Various exemplary embodiments of the systems and methods of this invention will be described in detail with reference to the following figures, wherein:

FIG. 1 is a view in perspective, showing the unassembled replacement sidewall and target/backing plate assembly in accordance with the invention;

FIG. 2 is a partial cross-sectional view of the replaceable sidewall insert and target/backing plate combination, showing the replacement sidewall in its disposition prior to assembly;

FIG. 3 is a view similar to FIG. 2 showing the sidewall in its inserted disposition in the target/backing plate groove; and

FIG. 4 is a view similar to FIG. 3 but showing an alternative embodiment of the replaceable sidewall in accordance with the invention.

### DETAILED DESCRIPTION OF EXEMPLARY EMBODIMENTS

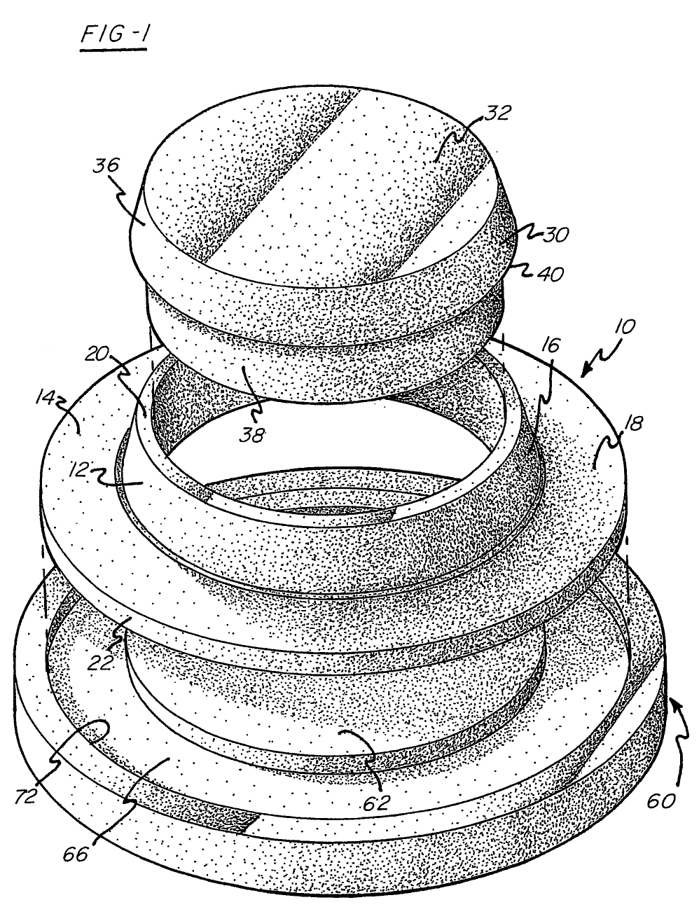

Turning first to FIG. 1, there is shown a replaceable target sidewall insert 10 in the general shape of an annulus. The insert is adapted to be placed around the circumference of the target in a target/backing plate assembly.

The sidewall insert includes an upstanding first leg member 12 and a horizontally connected second leg 14 with the first and second legs being generally perpendicularly disposed relative to each other. The outer surface 16 of the leg 12 is provided with a textured surface. This textured surface may be accomplished via conventional techniques, such as bead blasting, knurling, etching, machining, or by using a foamed metal as the member 10. At present, it is preferred to provide a textured coating via an arc spraying method. This textured coating may comprise materials such as Al and Cu and alloys thereof.

The leg 14 is also provided with a face surface 18 that can be similarly textured. The top portion of the leg 12 is shown by reference numeral 20 and defines the vertical boundary of the sidewall insert 10. Similarly, the peripheral boundary of the sidewall insert is shown at surface 22.

Turning briefly to FIG. 4, there is shown one particular embodiment of the invention wherein a thinned portion 24 is provided at the vertex between legs 12 and 14. This prethinned section may be cut in the sidewall insert so as to increase the springiness or elasticity of the insert to aid in removal and installation of the insert into the grooves that are provided in the target and backing plate.

Turning back to FIGS. 1-3 there is shown a target 30 of the type normally employed in cathodic sputtering systems to provide the desired uniform coating onto the substrate. The target comprises a sputter surface 32 from which desired metal atoms are ejected in the sputtering process to deposit onto the wafer or the like that is disposed proximate the anode in the system. The target comprises a lower surface 34 and a sidewall 36 extending around the circumference of the target.

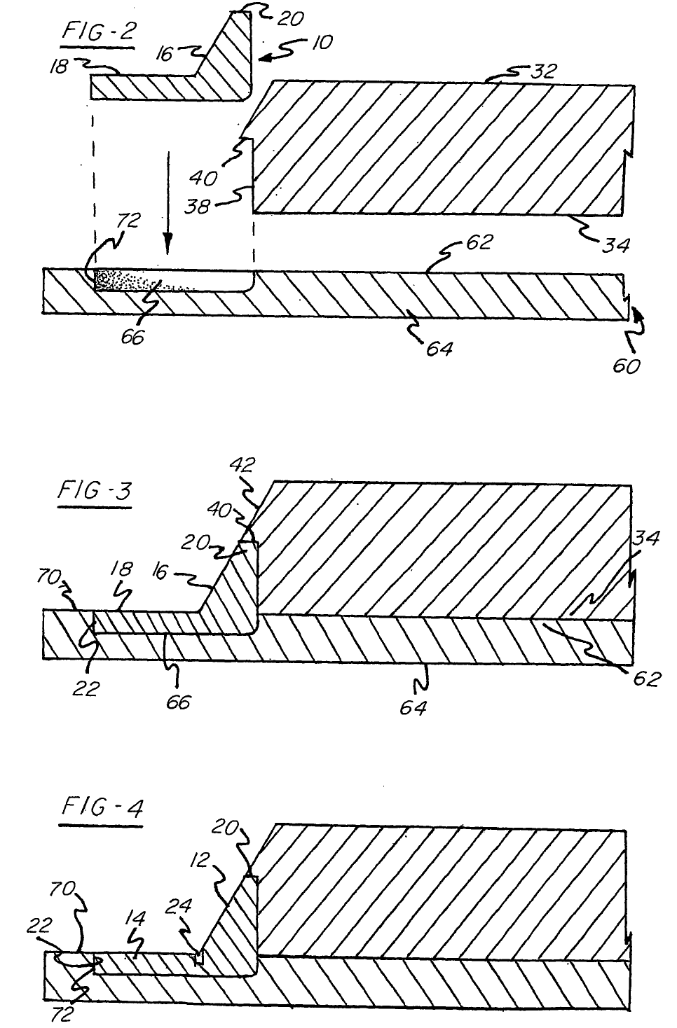

An upstanding groove 38 is provided in the sidewall 36, and a lip member 40 protrudes radially outwardly from the target to form a mechanical stop with the top portion 20 of the insert snugly received under the lip as shown. Note especially in FIG. 3 that the sidewall surface 42 of the target and the outer surface 16 of the replaceable target sidewall insert provide a smooth, continuous, linear surface area.

Again, with respect to FIGS. 1-3, a backing plate of the type conventionally employed is provided. Backing plate 60 comprises top surface 62 adapted to form an interfacial joined surface with the lower surface 34 of the target. An opposing lower surface 64 is provided on the underside of the backing plate and is adapted for heat exchange contact with a heat exchange medium, traditionally water. The circumferential top surface of the backing plate radially protruding away from the target is provided with an annular groove 66 therein adapted for receipt of the second leg 14 of the insert therein. The lateral, circumferential extremity 22 of the insert is snuggly received by the peripheral boundary 72 of the annular groove 66.

As shown best in FIG. 3, it is noted that the top surface 70 of the perimeter portion of the backing plate and the face surface 18 of the second leg of the insert provide a smooth, continuous, linear surface. Again, the face surface 18 of the sidewall insert is also preferably textured in order to increase particle retention thereon.

The insert 10 may be snugly snap fit or the like into the communicating grooves formed in the target sidewall and backing plate top surface. Additionally, fasteners such as bayonet mounts and slots and ball detents as shown in U.S. Pat. Nos. 4,820,397 and 5,147,521 may also be used to promote fastening of the insert to the target/backing plate assembly.

As shown, the outer surface 16 of leg 12 is in contiguous alignment with the target sidewall surface 42. The surfaces 42 and 16 define a continuous, linear surface area in the embodiments shown.

Overall, the cross-sectional shape of the insert can be viewed as being substantially L-shaped with the first and second legs of the insert oriented so as to form the substantial L-shaped cross section. The second leg member 14 of the insert and specifically its face surface thereof 18 forms a continuous surface with the perimeter surface portion 70 of the backing plate.

While this invention has been described in conjunction with the various exemplary embodiments described above, it is evident that many alternatives, combinations, modifications and variations are apparent to those skilled in the art. Accordingly, the exemplary embodiments of the invention set forth above are intended to be illustrative, and not limiting. Various changes can be made without departing from the spirit and scope of this invention.

1. In a sputter target/backing plate assembly of the type wherein said sputter target comprises a sputtering surface, a target sidewall surrounding said sputtering surface, a target bottom surface joined to said backing plate and a sidewall channel formed in said target sidewall, a replaceable target sidewall insert, said target sidewall insert adapted for snug receipt thereof in said target sidewall channel, said replaceable target insert comprising an outer sidewall surface adapted for contiguous alignment with said target sidewall, said outer sidewall surface comprising a textured surface receptive to particle attachment thereto.

2. Replaceable target sidewall insert as recited in claim 1 wherein said target sidewall and said outer sidewall surface of said replaceable target sidewall insert define a continuous linear surface area.

3. Replaceable target sidewall insert as recited in claim 2 wherein said target comprises a lip substantially perpendicularly disposed relative to said target sidewall and extending outwardly from said target sidewall, said replaceable target sidewall insert adapted for snug, abutting engagement with said lip while disposed within said target sidewall channel.

4. Replaceable target sidewall insert as recited hi claim 3, in the form of an annulus.

5. Replaceable insert as recited in claim 3 wherein said backing plate has a receipt groove therein in substantially perpendicular disposition with and communicating with said target sidewall channel, said replaceable target sidewall insert having a substantially L-shaped cross-sectional configurational shape comprising first and second leg members oriented substantially perpendicularly to each other and forming said substantially L-shaped cross-sectional configuration, said first leg member including said outer sidewall surface, said second leg member having a face surface adapted for forming a continuous surface with said backing plate, said face surface also comprising a textured surface receptive to particle attachment thereto.

6. Replaceable target sidewall insert as recited in claim 1 wherein said outer sidewall surface of said insert is adapted for continuous, linear disposition alongside said target sidewall.

7. Replaceable target sidewall insert as recited in claim 1 wherein said target sidewall insert comprises a thinned cross-sectional area to aid in installation and removal of said replaceable target sidewall insert from said target/backing plate assembly.

8. Replaceable target sidewall insert as recited in claim 5, wherein said textured surfaces of both said outer sidewall surface and said face surface of said insert are formed via arc spraying, bead blasting, etching, or machining.

9. Replaceable target sidewall insert as recited in claim 5 composed of foamed metal.

10. A target and backing plate assembly comprising:
a target;
a backing plate, the target attached to the backing plate and forming an interface therebetween; and
a removable member joining the target and backing plate at the interface.

11. The target and backing assembly of claim 10, wherein the removable member includes a horizontal portion and a vertical portion joined to form a substantially L-shaped removable member.

12. The target and backing assembly of claim 11, wherein the horizontal portion of the removable member is fitted into a groove on the backing plate, the groove comprising an outer wall, an inner wall and a floor, and the vertical portion of the removable member is fitted along a straight portion of the target extending away from the backing plate.

13. The target and backing plate assembly of claim 12 wherein the straight portion of the target ends in a lip projecting outwardly from the target substantially parallel to the backing plate such that the vertical portion of the removable member abuts the lip when fitted to the assembly.

14. The target and backing plate assembly of claim 12, wherein the removable member is provided with a textured outer surface.

15. The target and backing plate assembly of claim 14, wherein the textured coat is applied by arc spraying.

16. The target and backing plate assembly of claim 14 wherein said removable member is composed of a foamed metal.

17. The target and backing plate assembly of claim 14 wherein said removable member is composed of a shape memory metal.

18. The target and backing plate assembly of claim 14 wherein said removable member is a metal having a negative coefficient of thermal expansion.

19. The target and backing assembly of claim 10, wherein the removable insert further comprises a pre-thinned area aiding installation and removal of the removable insert from the assembly.

20. A removable insert for use with a target and backing plate assembly, the removable insert comprising:
a vertical portion;
a horizontal portion, the vertical portion joining the horizontal portion; and
a textured surface on the vertical and horizontal portions, whereby the vertical portion is adapted for alignment with a sidewall of the target and the horizontal portion is adapted for alignment with a portion of an upper surface of the backing plate.

21. The removable insert of claim 20, wherein the textured surface is comprised of a metal alloy.

22. The removable insert of claim 21, wherein the textured surface is applied by arc spraying.

23. The removable insert of claim 20 wherein said insert is composed of a foamed metal.

24. The removable insert of claim 20, wherein a pre-thinned portion joins the vertical portion and horizontal portion, the pre-thinned portion adapted to aid installation and removal of the insert from the assembly.

25. The removable insert of claim 20 wherein said insert is composed of a shape memory metal.

26. The removable insert of claim 20 wherein said insert is composed of a metal having a negative coefficient of thermal expansion.
